(19) United States
(12) Patent Application Publication
(10) Pub. No.: US 2026/0293326 A1
(43) Pub. Date: Sep. 24, 2026

(54) PHOTOVOLTAIC MODULES WITH GLASS FRIT SEALS & METHODS OF MAKING THE SAME

(71) Applicant: CORNING INCORPORATED, CORNING, NY (US)

(72) Inventors: Sean Matthew Garner, Elmira, NY (US); Kuan-Ting Kuo, Chubei (TW); Jen-Chieh Lin, San Jose, CA (US); Lu Zhang, Taipei (TW)

(21) Appl. No.: 19/472,299

(22) PCT Filed: May 9, 2024
(86) PCT No.: PCT/US2024/028516

§ 371 Date: Oct. 3, 2025

Related U.S. Application Data
(60) Provisional application No. 63/465,286, filed on May 10, 2023.

(51) Int. Cl. H10F 19/80

(52) U.S. Cl. CPC H10F 19/804; H10F 19/807

(57) ABSTRACT

A photovoltaic module (and steps for making it) that includes: an outer glass layer; an inner glass layer; one or more photovoltaic (PV) structures disposed on the outer glass layer, inner glass layer or between the layers; a polymeric seal disposed between and in contact with the inner and outer glass layers; and a first glass frit disposed between and in contact with the inner and outer glass layers. The seal width of the first glass frit is at least about 100 μm. Further, the module exhibits no failures at the polymeric seal and first glass frit after 1200 hours of exposure at 85° C. and 85% relative humidity according to the 85/85 Test. In addition, some modules include a second glass frit disposed between and in contact with the inner and outer glass layers.

### CROSS-REFERENCE TO RELATED DISCLOSURES

This application claims the benefit of priority under 35 U.S.C. § 119 of U.S. Provisional Application No. 63/465,286 filed May 10, 2023, the content of which is incorporated herein by reference in its entirety.

### FIELD OF THE DISCLOSURE

The present disclosure relates to photovoltaic (PV) modules and methods of making PV modules, particularly, solar modules for various end use applications, including utility, residential and commercial markets.

### BACKGROUND

Conventional PV modules have been successfully used in various power generation applications. Demand for PV modules remains high, and only appears to be increasing, given the significant reduction in power generation-related emissions associated with this technology as compared to existing methods, e.g., coal and natural gas. But challenges do remain for widespread adoption of PV modules for power generation, including conversion efficiency, cost and reliability.

One significant challenge for conventional PV modules is long-term reliability, especially in climate extremes and desired lifetimes that exceed 30 years. The PV cells and structures within these modules work by converting photons of sunlight into electricity directly by using semiconducting materials that exhibit a photovoltaic effect. Photon absorbance efficiency of these PV modules can be improved by outdoor use, e.g., with ground-, rooftop-, and wall-mounted PV module arrangements. However, these conventional PV modules installed outdoors can experience premature failures and unacceptable reductions in conversion efficiency over their lifetime. Notably, many conventional PV technologies are susceptible to the presence of oxygen and/or water, e.g., organic PV materials, dye-sensitized solar cells, perovskite PV materials, etc.

Conventional PV modules have used polymer resins to prevent moisture and oxygen ingress. Polymer resins, however, can age relatively quickly in outdoor environments, particularly with exposure to climate extremes and ultraviolet radiation. Other sealing technologies, such as glass frit seals, have been successfully employed to hermetically seal electronic display devices, e.g., organic light emitting diode (OLED) modules. However, these OLED electronic devices, and their glass frit seals, are typically configured for indoor use only with relatively short lifetimes of less than 10 years and modest moisture ingress requirements as compared to PV modules suitable for outdoor use (e.g., 30+ year lifetime, exposure to 85% relative humidity and 85° C. for at least 1200 hours without failure, etc.).

Accordingly, there is a need for PV module configurations, manufacturing methods, and design approaches which offer improved long-term reliability under exposure to various climate conditions, including high humidity and liquid water exposure (e.g., as manifested in a 85% relative humidity and 85° C. test conducted for at least 1200 hours).

### SUMMARY

According to an aspect of the disclosure, a photovoltaic module is provided that includes: an outer glass layer; an inner glass layer; one or more photovoltaic (PV) structures disposed on the outer glass layer, inner glass layer or between the layers; a polymeric seal disposed between and in contact with the inner and outer glass layers; and a first glass frit disposed between and in contact with the inner and outer glass layers. The seal width of the first glass frit is at least about 100 μm. Further, the module exhibits no failures at the polymeric seal or first glass frit after 1200 hours of exposure at 85° C. and 85% relative humidity according to the 85/85 Test (see below for details).

According to another aspect of the disclosure, a photovoltaic module is provided that includes an outer glass layer; an inner glass layer; one or more photovoltaic (PV) structures disposed on the outer glass layer, inner glass layer or between the layers; a polymeric seal disposed between and in contact with the inner and outer glass layers; a first glass frit disposed between and in contact with the inner and outer glass layers; and a second glass frit disposed between and in contact with the inner and outer glass layers. The seal width of the first and second glass frits is at least about 100 μm. Further, the module exhibits no failures at the polymeric seal or glass frits after 1200 hours of exposure at 85° C. and 85% relative humidity according to the 85/85 Test.

According to a further aspect of the disclosure, a method of making a photovoltaic module is provided that includes the following steps: dispensing a first glass frit on an inner glass layer, the first glass frit defining a seal width of at least about 100 μm; positioning one or more photovoltaic (PV) structures on the inner glass layer; sintering the first glass frit; dispensing a polymeric seal on the inner glass layer; positioning an outer glass layer in contact with the first glass frit and the polymeric seal, the positioning conducted such that the first glass frit and the polymeric seal are disposed between and in contact with the inner and outer glass layers; irradiating the glass frit with a laser such that a portion of the first glass frit is in contact with the inner and outer glass layers, the portion having an average bond width that is at least 90% of the seal width of the first glass frit; and curing the polymeric seal.

Each of the foregoing PV modules and methods, and variants consistent with one or more of their concepts, can offer improved long-term module reliability in the face of extreme climate conditions, as exemplified by the 85/85 Test (detailed below).

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a plan view of a photovoltaic module, according to one or more embodiments of the disclosure;

FIG. 1A is a cross-sectional side view of the photovoltaic module taken at line IA of FIG. 1;

FIG. 2 is a plan view of a photovoltaic module, according to one or more embodiments of the disclosure;

FIG. 2A is a cross-sectional side view of the photovoltaic module taken at line IIA of FIG. 2;

FIG. 3 is a plan view of an exemplary photovoltaic module, according to one or more embodiments of the disclosure;

FIG. 3A is a cross-sectional side view of the photovoltaic module taken at line IIIA of FIG. 3;

FIG. 4 is a flow chart schematic of a method of making a photovoltaic module, according to one or more embodiments of the disclosure;

FIG. 5A is a height profile of a sintered glass frit on a glass layer, according to one or more embodiments of the disclosure;

FIG. 5B is an optical micrograph of a top-down view of the glass frit of FIG. 5A, as irradiated to form a seal between two glass layers, according to one or more embodiments of the disclosure;

FIGS. 6A and 6B are optical micrographs of a top-down view of comparative as-irradiated glass frit seals in sample photovoltaic modules that also include polymeric seals with delamination and cracking failure modes, respectively;

FIGS. 7A and 7B are optical micrographs of a top-down view of as-irradiated glass frit seals in sample photovoltaic modules that also include polymeric seals, according to one or more embodiments of the disclosure; and

FIGS. 8-10 are optical micrographs of a top-down view of as-irradiated glass frit seals in sample photovoltaic modules that also include polymeric seals, as subjected to the 85/85 Test, according to one or more embodiments of the disclosure.

### DETAILED DESCRIPTION

In the following detailed description, for purposes of explanation and not limitation, example embodiments disclosing specific details are set forth to provide a thorough understanding of various principles of the present disclosure. However, it will be apparent to one having ordinary skill in the art, having had the benefit of the present disclosure, that the present disclosure may be practiced in other embodiments that depart from the specific details disclosed herein. Moreover, descriptions of well-known devices, methods and materials may be omitted so as not to obscure the description of various principles of the present disclosure. Finally, wherever applicable, like reference numerals refer to like elements.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example “up,” “down,” “right,” “left,” “front,” “back,” “top,” “bottom”—are made only with reference to the figures as drawn and are not intended to imply absolute orientation.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

As used herein, the singular forms “a,” “an” and “the” include plural referents unless the context clearly dictates otherwise. Thus, for example, reference to a “component” includes aspects having two or more such components, unless the context clearly indicates otherwise.

As used herein, the term “dispose” includes coating, depositing, and/or forming a material onto a surface using any known or to be developed method in the art. The disposed material may constitute a layer, as defined herein. As used herein, the phrase “disposed on” includes forming a material onto a surface such that the material is in direct contact with the surface and embodiments where the material is formed on a surface with one or more intervening material(s) disposed between the material and the surface. The intervening material(s) may constitute a layer, as defined herein.

As used herein, the term “strengthened substrate” refers to a substrate of the disclosure that has been chemically strengthened, for example through ion-exchange of larger ions for smaller ions in the surface of the substrate. In addition, other strengthening methods known in the art, such as thermal tempering, or utilizing a mismatch of the coefficient of thermal expansion between portions of the substrate to create compressive stress and central tension regions, may be utilized to form “strengthened substrates”.

As used herein, the “85/85 Test” is conducted on PV modules and samples outlined in this disclosure according to the IEC 61215-1:2021 Protocol for crystalline silicon PV modules, Damp Heat Test. In particular, according to the 85/85 Test, samples are tested in an uninterrupted manner in a test environment of 85% relative humidity and a temperature of 85° C.±2° C. for 1000 hours of exposure, 1200 hours of exposure (50 days), or other specified duration, in a thermal chamber (e.g., Thermotro SM-8-8200). Unless otherwise noted, the dimensions of the samples are as noted and samples sizes are selected to generate statistically significant data as understood by those skilled in the field of the disclosure.

Generally, the disclosure is directed to photovoltaic (PV) modules (and methods of making them) that offer improved long-term reliability under exposure to various climate conditions, including high humidity and liquid water exposure (e.g., as manifested in a 85% relative humidity and 85° C. test conducted for at least 1200 hours). The PV modules of this disclosure are glass laminates that employ conventional PV structures and utilize a polymeric seal and at least one glass frit seal. The glass laminates can have glass on both module front and back surfaces or, in general, have a polymer, metal, or composite back-sheet. Advantageously and surprisingly, the laminates employ a dual-seal scheme in which the polymeric seal can prevent liquid water ingress, and the glass frit seal can prevent moisture (e.g., at 85% relative humidity) and gaseous ingress (e.g., oxygen, nitrogen, ambient air, etc.), at an elevated temperature (e.g., 85° C.) over exceedingly long timeframes (e.g., at least 1200 hours). Ultimately, these PV modules can be employed in various utility, residential, vehicular, aviation, and commercial power-generation applications. Further, these PV modules can be employed in applications with increased sensitivity to oxygen and moisture that will be exposed to uncontrolled environments for extended lifetimes, e.g., outdoor utility-scale installations with PV modules, building-integrated PV modules, vehicle-integrated PV modules, aviation-oriented PV modules, and others.

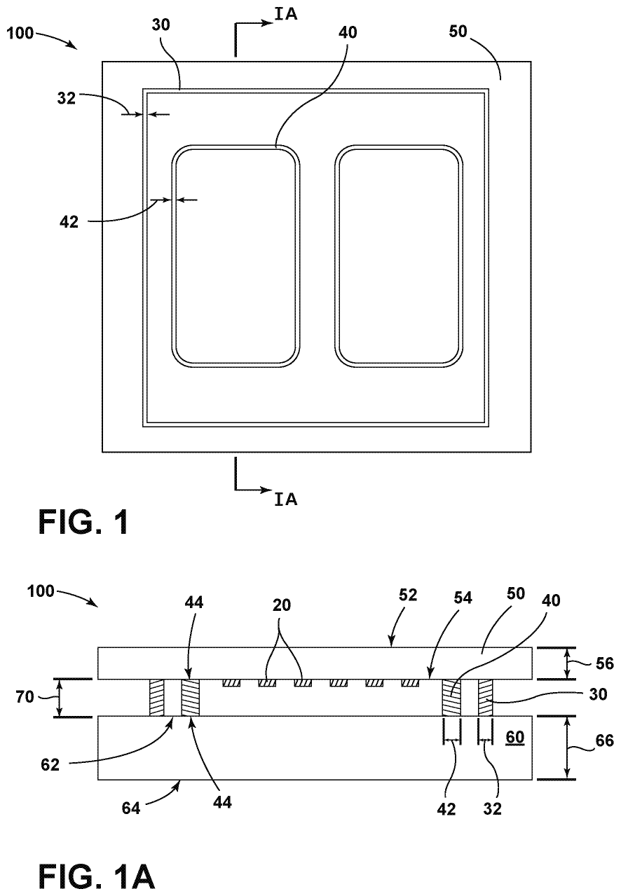

Reference will now be made in detail to various embodiments of photovoltaic (PV) modules, examples of which are illustrated in the accompanying drawings. Referring to FIGS. 1 and 1A, an exemplary PV module 100 can include: an outer glass layer 50; an inner glass layer 60; one or more photovoltaic (PV) structures 20 disposed on the outer glass layer 50, inner glass layer 60 or between the layers 50, 60. Further, PV module 100 includes a polymeric seal 30 with a width 32 disposed between and in contact with the inner glass layer 60 and outer glass layer 50; and a first glass frit 40 with a width 42 disposed between and in contact with the inner and outer glass layers 60, 50. It should be understood that the width 32 of the polymeric seal 30 and the width 42 of the first glass frit 40 can have same width values, they may differ from one another and/or these values can be constant or vary within a given module. Further, the first glass frit 40 and polymeric seal 30 can define a gap 70 set between the inner and outer glass layers 60, 50. With further regard to the PV module 100 shown in FIGS. 1, 1A, the outer glass layer 50 can define an outer primary surface 52 and an inner primary surface 54 opposing the outer primary surface 52, along with a thickness 56. Similarly, the inner glass layer 60 can define an outer primary surface 62 and an inner primary surface 64 opposing the outer primary surface 62, along with a thickness 66.

According to implementations of the PV module 100 depicted in FIGS. 1, 1A, the width 42 of the first glass frit 40 can be set to at least about 100 μm, at least about 250 μm, at least about 400 μm, at least about 600 μm, or at least 750 μm. For example, the width 42 of the first glass frit 50 can be 100 μm, 200 μm, 300 μm, 400 μm, 450 μm, 500 μm, 550 μm, 600 μm, 650 μm, 700 μm, 750 μm, 800 μm, and other widths 42 between the foregoing width values. Without being bound by theory, the width 42 of the first glass frit 40 can be set to improve the hermeticity and moisture resistance of the PV module 100. Additionally, the width 42 of the first glass frit 50 can vary along the perimeter of the PV module 100. For example, width 42 of the first glass frit 50 can be wider at the corners, wider along the edges, or wider while traversing across electrodes or metal lines.

In some embodiments of the PV module 100 depicted in FIGS. 1, 1A, the first glass frit 40 may define one or more portions 44 that are in contact with an inner glass layer 60 and/or outer glass layer 50. As shown in exemplary form in FIGS. 1, 1A, the portions 44 of the first glass frit 40 are shown in contact with the outer and inner glass layers 50, 60 and these portions define a bond width between the layers 50, 60. In some embodiments, the portions 44 of the first glass frit 40 define an average bond width that is substantially the same as the width 42 of the first glass frit 40. In other embodiments, the portions 44 of the first glass frit 40 define an average bond width of at least 80%, at least 90%, or even at least 95% of the width 42 of the first glass frit 40. Without being bound by theory, the portions 44 of the first glass frit 40 are maximized to improve the hermeticity and moisture resistance of the PV module 100. The portions 44 of the glass frit 40 in contact with outer glass layer 50 and inner glass layer 60 do not need to be the same. For example, the frit bond with glass layer 50 may be larger, smaller, or substantially the same as the frit bond with glass layer 60.

According to some implementations of the PV module 100 depicted in FIGS. 1, 1A, the first glass frit 40 is arranged within the module in an inboard location relative to the location of the polymeric seal 30. In embodiments, the first glass frit 40 can be inboard and in contact with the polymeric seal 30 or set apart from the polymeric seal at a specified distance. Preferably, the first glass frit 40 is also set at some distance outboard from the outermost one or more photovoltaic structures 20, as shown in exemplary form in FIGS. 1, 1A. Without being bound by theory, the PV module 100 being configured with an inboard glass frit 40 ensures that the glass frit is not subjected to direct water exposure as the outboard polymeric seal 30 can prevent contact of water with the glass frit 40. As such, the glass frit 40 is not subjected to direct water exposure ensuring that it can serve to provide a moisture and gaseous barrier.

In some embodiments of the PV module 100 depicted in FIGS. 1, 1A, the first glass frit 40 and the polymeric seal 30 define a gap 70 between the inner and outer glass layers 60, 50 from about 1 μm to 100 μm, 2.5 μm to 50 μm, from 5 μm to 20 μm, or all gaps 70 and ranges of gaps 70 between the foregoing values. For example, the gap 70 can be set at about 1 μm, 2 μm, 3 μm, 4 μm, 5 μm, 6 μm, 7 μm, 8 μm, 9 μm, 10 μm, 12.5 μm, 15 μm, 17.5 μm, 20 μm, 25 μm, 50 μm, 75 μm, 100 μm, and all gap values between the foregoing levels. Along with the PV cell and electronic structures, this gap 70 can also be filled with adhesive, gas, liquid, or composite materials. In addition, according to some embodiments, the gap 70 can be in the range of from 100 m to 1000 μm.

In this superstrate configuration of the PV module 100 depicted in FIGS. 1, 1A, solar radiation is incident on the outer primary surface 52 of the outer glass layer 50 and is converted to power (e.g., electricity) by the one or more PV structures 20. PV substrate configurations are also possible where light is incident into the system at primary surface 64 of the inner glass layer 60. In embodiments, the one or more PV structures 20 are disposed in close proximity to, or in contact with, the inner primary surface 54 of the outer glass layer 50. In other embodiments, the one or more PV structures 20 are disposed in close proximity to, or in contact with, the outer primary surface 62 of the inner glass layer 60 (not shown), or between the layers 50, 60. The polymeric seal 30 and first glass frit 40, as depicted in FIGS. 1, 1A, reside between the outer glass layer 50 and inner glass layer 60 and are generally configured to adhere the outer and inner glass layers 50, 60 together. Collectively, the polymeric seal 30 and first glass frit 40 can serve to hermetically seal the one or more PV structures 20 from the outside environment. Further, in some embodiments of the PV module 100, the polymeric seal 30 and/or additional portions of the same material can encapsulate the one or more PV structures 20 such that the one or more PV structures 20 are isolated from the inner glass layer 50 (e.g., electrically, from solid state diffusion of alkali metals in the glass composition, etc.) (not shown in FIGS. 1, 1A).

With regard again to the photovoltaic module 100 depicted in exemplary form in FIGS. 1, 1A, various photovoltaic structures are suitable for use in the one or more PV structures 20 employed in the module 100. According to some embodiments, the one or more PV structures 20 can be presented in a variety of forms including, but not limited to, wafered-Si, for example, crystalline silicon, macrocrystalline silicon, microcrystalline silicon, other wafer-based PV, or combinations thereof. In some implementations, for example, each PV structure 20 can be one of a CdTe, amorphous silicon (a-Si), polysilicon (p-Si), CuIn/GaSe (CIGS), organic small-molecule, organic polymer, and perovskite (ABX₃), and other thin-film PV structures. Further, according to some embodiments of the PV module 100, the one or more PV structures 20 are formed as thin-film structures in the form of a layer having a thickness of less than 10 μm. The PV structure(s) 20 may also be a combination of technologies to create tandem cells or other structures. These PV structure(s) 20 can be in contact or near proximity to outer glass layer 50 and/or inner glass layer 60. These one or more PV structures 20 can also be not in near proximity or contact with either glass layer 50, 60. Besides sealing the PV structure(s) 20, the sealing can also encapsulate additional devices integrated with the PV structure(s) 20 within the same area.

According to some implementations of the PV module 100 depicted in FIGS. 1, 1A, each of the thicknesses 56, 66 of the outer and inner glass layers 50, 60 can range from 50 to 5000 μm, 50 to 4000 μm, 50 to 3000 μm, 50 to 2000 μm, 50 to 1000 μm, 100 to 750 μm, 100 to 600 μm, 100 to 500 jμm, 150 to 500 μm, and all thickness sub-ranges between the foregoing ranges. For example, the thickness 56 of the outer glass layer 50 and/or thickness 66 of the inner glass layer 60 can be about 50, 100, 150, 200, 250, 300, 350, 400, 450, 500, 600, 700, 800, 900, 1000, 1250, 1500, 1750, 2000, 2500, 3000, 3500, 4000, 4500, 5000 μm, and all thickness values between the foregoing thickness values. In some implementations, the PV module 100 is asymmetric in the sense that the outer glass layer 50 is thinner than the inner glass layer 60, or vice versa. In further implementations, the shape of the outer and inner glass layers 50, 60 can be any of a variety of shapes, including rectangular, square, oval, circular, and other arbitrary shapes. Additionally, one of the glass layers 50, 60 can be replaced by a metal, polymer, ceramic, or composite material.

Referring again to the PV module 100 depicted in FIGS. 1, 1A, its outer glass layer 50 can be thinner than the inner glass layer 60. In some implementations, the composition of outer glass layer 50 is selected from any of the various glass compositions classified by those skilled in the field of this disclosure as flexible glass (e.g., Corning® Willow® glass). Such glass compositions can be suitable to ensure that module 100 remains substantially failure-free (<1%) upon bending with a thickness 56 of the outer glass layer 50 ranging from 50 to 1000 μm. In some implementations, the composition of the outer glass layer 50 is substantially alkali metal-free, e.g., to further enhance device efficiency and reliability. In other embodiments, the composition of the outer glass layer 50 is selected with sufficient levels of alkali metal(s) (e.g., Na⁺, K⁺, Li⁺ ions, etc.) to facilitate strengthening through ion-exchange (IOX) processing, as detailed below.

Still referring to the PV module 100 depicted in FIGS. 1, 1A, its inner glass layer 60 can be thicker than the outer glass layer 50. In other implementations, the inner glass layer is thinner than the outer glass layer 50. In some implementations, the composition of the inner glass layer 60 can comprise a soda-lime glass (SLG) composition, other glass compositions with high optical transmittance and strength, e.g., tempered low-Fe SLG glass, or any other structural glass composition suitable for lamination to a thinner outer glass layer, e.g., an outer glass layer 50 with a flexible glass composition. Further, in some implementations, the composition of the inner glass layer 60 is selected to facilitate the development of a compressive stress region through an IOX process, e.g., a glass composition with sufficient levels of alkali metal(s). In addition, it should be understood that either or both of the outer and inner glass layers 50, 60 can have any of the foregoing glass compositions, e.g., an Ultra-Thin Flexible (UTF) glass composition (e.g., Corning® Willow® glass), a soda-lime glass (SLG) composition, other glass compositions with high optical transmittance and strength, e.g., tempered low-Fe SLG glass, or any other structural glass composition suitable for lamination, and/or a glass composition suitable for chemical strengthening (e.g., a composition with sufficient alkali metal(s) (e.g., Na⁺, K⁺, Li⁺ ions, etc.), thermal tempering or strengthening.

The outer and inner glass layers 50, 60 of the PV module 100 depicted in FIGS. 1, 1A may be provided using a variety of different processes. For instance, the various forming methods can include float glass processes and down-draw processes such as fusion draw and slot draw.

Referring again to the PV module 100 depicted in FIG. 1, the outer and inner glass layers 50, 60 are, in some embodiments, selected with compositions(s) such that they have the same or substantially the same coefficient of thermal expansion (CTE). In some embodiments, each of the outer and inner glass layers 50, 60 possess a CTE of less than about 10, 7.5, or even 5 ppm/° C. For example, each of the outer and inner glass layers 50, 60 can exhibit a CTE of 10, 9, 8, 7, 6, 5, 4, 3, 2, 1 ppm/° C., or other CTE value between the foregoing levels.

Once formed, either or both of the outer and inner glass layers 50, 60 may be strengthened to form a strengthened substrate. Where the outer and/or inner glass layers 50, 60 are chemically strengthened by an ion exchange process, the ions in the surface layer of the substrate are replaced by—or exchanged with—larger ions having the same valence or oxidation state. Ion exchange processes are typically carried out by immersing a substrate in a molten salt bath containing the larger ions to be exchanged with the smaller ions in the glass layer(s). It will be appreciated by those skilled in the art that parameters for the ion exchange process, including, but not limited to, bath composition and temperature, immersion time, the number of immersions of the glass layer(s) in a salt bath (or baths), use of multiple salt baths, and additional steps such as annealing, washing, and the like, are generally determined by the composition of the substrate and the desired compressive stress (CS), depth of compressive stress layer (or depth of layer DOL, or depth of compression DOC) of the substrate that result from the strengthening operation. By way of example, ion exchange of alkali metal-containing glass layer(s) may be achieved by immersion in at least one molten bath containing a salt such as, but not limited to, nitrates, sulfates, and chlorides of the larger alkali metal ion. The temperature of the molten salt bath typically is in a range from about 380° C. up to about 450° C., while immersion times range from about 15 minutes up to about 40 hours. However, temperatures and immersion times different from those described above may also be used.

In addition, non-limiting examples of ion exchange processes in which glass layer(s) 50, 60 are immersed in multiple ion exchange baths, with washing and/or annealing steps between immersions, are described in U.S. patent application Ser. No. 12/500,650, filed Jul. 10, 2009, by Douglas C. Allan et al., entitled “Glass with Compressive Surface for Consumer Applications,” and claiming priority from U.S. Provisional Patent Application No. 61/079,995, filed Jul. 11, 2008, in which glass layer(s) are strengthened by immersion in multiple, successive, ion exchange treatments in salt baths of different concentrations; and U.S. Pat. No. 8,312,739, by Christopher M. Lee et al., issued on Nov. 20, 2012, and entitled “Dual Stage Ion Exchange for Chemical Strengthening of Glass,” and claiming priority from U.S. Provisional Patent Application No. 61/084,398, filed Jul. 29, 2008, in which glass layer(s) are strengthened by ion exchange in a first bath diluted with an effluent ion, followed by immersion in a second bath having a smaller concentration of the effluent ion than the first bath. The contents of U.S. patent application Ser. No. 12/500,650 and U.S. Pat. No. 8,312,739 are incorporated herein by reference in their entirety.

The degree of chemical strengthening achieved by ion exchange may be quantified based on the parameters of central tension (CT), surface CS, and depth of compression (DOC). Compressive stress (including surface CS) is measured by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety. Maximum CT values are measured using a scattered light polariscope (SCALP) technique known in the art. As used herein, DOC means the depth at which the stress in the chemically strengthened alkali aluminosilicate glass layer(s) described herein changes from compressive to tensile. DOC may be measured by FSM or SCALP depending on the ion exchange treatment. Where the stress in the glass layer(s) is generated by exchanging potassium ions into the glass layer(s), FSM is used to measure DOC. Where the stress is generated by exchanging sodium ions into the glass layer(s), SCALP is used to measure DOC. Where the stress in the glass layer(s) is generated by exchanging both potassium and sodium ions into the glass, the DOC is measured by SCALP, since it is believed the exchange depth of sodium indicates the DOC and the exchange depth of potassium ions indicates a change in the magnitude of the compressive stress (but not the change in stress from compressive to tensile); the exchange depth of potassium ions in such glass layer(s) is measured by FSM.

In one embodiment, either or both of the outer and inner glass layers 50, 60 can have a surface CS of 250 MPa or greater, 300 MPa or greater, e.g., 400 MPa or greater, 450 MPa or greater, 500 MPa or greater, 550 MPa or greater, 600 MPa or greater, 650 MPa or greater, 700 MPa or greater, 750 MPa or greater or 800 MPa or greater. The strengthened substrate may have a DOC of 10 μm or greater, 15 μm or greater, 20 μm or greater (e.g., 25 μm, 30 μm, 35 μm, 40 μm, 45 μm, 50 μm or greater) and/or a CT of 10 MPa or greater, 20 MPa or greater, 30 MPa or greater, 40 MPa or greater (e.g., 42 MPa, 45 MPa, or 50 MPa or greater) but less than 100 MPa (e.g., 95, 90, 85, 80, 75, 70, 65, 60, 55 MPa or less). In one or more specific embodiments, the strengthened substrate (i.e., outer and/or inner glass layers 50, 60) has one or more of the following: a surface CS greater than 500 MPa, a DOC greater than 15 μm, and a CT greater than 18 MPa. In some implementations, the compressive stress region of either or both of the outer and inner glass layers 50, 60 may be at least 20% of its thickness 56, 66 and exhibit a CS of at least 800 MPa.

Example glasses that may be used for the outer and inner glass layers 50, 60, including those that are processed to be a ‘strengthened substrate,’ may include alkali aluminosilicate glass compositions or alkali aluminoborosilicate glass compositions, though other glass compositions are contemplated. Such glass compositions are capable of being chemically strengthened by an ion exchange process. One example glass composition comprises SiO₂, B₂O₃ and Na₂O, where (SiO₂+B₂O₃)≥66 mol. %, and Na₂O≥9 mol. %. In an embodiment, the glass composition includes at least 6 wt. % aluminum oxide. In a further embodiment, the substrate includes a glass composition with one or more alkaline earth oxides, such that a content of alkaline earth oxides is at least 5 wt. %. Suitable glass compositions, in some embodiments, further comprise at least one of K₂O, MgO, and CaO. In a particular embodiment, the glass compositions used in either or both of the outer and inner glass layers 50, 60 can comprise 61-75 mol. % SiO₂; 7-15 mol. % Al₂O₃; 0-12 mol. % B₂O₃; 9-21 mol. % Na₂O; 0-4 mol. % K₂O; 0-7 mol. % MgO; and 0-3 mol. % CaO.

A further example glass composition suitable for either or both of the outer and inner glass layers 50, 60 comprises: 60-70 mol. % SiO₂; 6-14 mol. % Al₂O₃; 0-15 mol. % B₂O₃; 0-15 mol. % Li₂O; 0-20 mol. % Na₂O; 0-10 mol. % K₂O; 0-8 mol. % MgO; 0-10 mol. % CaO; 0-5 mol. % ZrO₂; 0-1 mol. % SnO₂; 0-1 mol. % CeO₂; less than 50 ppm As₂O₃; and less than 50 ppm Sb₂O₃; where 12 mol. % (Li₂O+Na₂O+K₂O) 20 mol. % and 0 mol. %≤(MgO+CaO)≤10 mol. %. A still further example glass composition suitable for either or both of the outer and inner glass layers 50, 60 comprises: 63.5-66.5 mol. % SiO₂; 8-12 mol. % Al₂O₃; 0-3 mol. % B₂O₃; 0-5 mol. % Li₂O; 8-18 mol. % Na₂O; 0-5 mol. % K₂O; 1-7 mol. % MgO; 0-2.5 mol. % CaO; 0-3 mol. % ZrO₂; 0.05-0.25 mol. % SnO₂; 0.05-0.5 mol. % CeO₂; less than 50 ppm As₂O₃; and less than 50 ppm Sb₂O₃; where 14 mol. %≤(Li₂O+Na₂O+K₂O)≤18 mol. % and 2 mol. %≤(MgO+CaO)≤7 mol. %.

In a particular embodiment, an alkali aluminosilicate glass composition suitable for either or both of the outer and inner glass layers 50, 60 comprises alumina, at least one alkali metal and, in some embodiments, greater than 50 mol. % SiO₂, in other embodiments at least 58 mol. % SiO₂, and in still other embodiments at least 60 mol. % SiO₂, wherein the ratio (Al₂O₃+B₂O₃)/Σmodifiers (i.e., sum of modifiers) is greater than 1, where in the ratio the components are expressed in mol. % and the modifiers are alkali metal oxides. This glass composition, in particular embodiments, comprises: 58-72 mol. % SiO₂; 9-17 mol. % Al₂O₃; 2-12 mol. % B₂O₃; 8-16 mol. % Na₂O; and 0-4 mol. % K₂O, wherein the ratio (Al₂O₃+B₂O₃)/Σmodifiers (i.e., sum of modifiers) is greater than 1.

In still another embodiment, either or both of the outer and inner glass layers 50, 60 may include an alkali aluminosilicate glass composition comprising: 64-68 mol. % SiO₂; 12-16 mol. % Na₂O; 8-12 mol. % Al₂O₃; 0-3 mol. % B₂O₃; 2-5 mol. % K₂O; 4-6 mol. % MgO; and 0-5 mol. % CaO, wherein: 66 mol. %≤SiO₂+B₂O₃+CaO≤69 mol. %; Na₂O+K₂O+B₂O₃+MgO+CaO+SrO>10 mol. %; 5 mol. %≤MgO+CaO+SrO≤8 mol. %; (Na₂O+B₂O₃)−Al₂O₃≤2 mol. %; 2 mol. %≤Na₂O−Al₂O₃≤6 mol. %; and 4 mol. %≤(Na₂O+K₂O)−Al₂O₃≤10 mol. %. Thermal tempering, thermal strengthening, or other methods are also possible.

Referring again to the PV module 100 depicted in FIGS. 1, 1A, the module includes a polymeric seal 30 that is disposed between and in contact with the outer glass layer 50 and inner glass layer 60. In embodiments, the polymeric seal 30 is selected to adhere the outer and inner glass layers 50, 60 together with a high peel strength as measured between them and, preferably, with a low water vapor transmission rate. Suitable CTE levels for the polymeric seal 30 can range from 5 to 200 ppm/° C., 75 to 175 ppm/° C., and all CTE levels in the foregoing ranges. Suitable polymeric seal 30 materials include, but are not limited to, silicone, ionomer (e.g., SentryGlas® made by Kuraray America), epoxy, thermoplastic polyolefin (TPO), polyolefin (PO), polyvinyl butyral (PVB), thermoplastic polyurethane (TPU) (e.g., BETASEL X2500 made by Dow), and ethylene vinyl acetate (EVA) adhesives. Suitable epoxies include ultraviolet (UV) cationic epoxy adhesives that are primarily composed of epoxy resin and a cationic photoinitiator, e.g., cycloaliphatic-type epoxy resins. Two common epoxy resins employed in cationic epoxy adhesives are 3, 4-epoxycylohexylmethyl-3, 4-epoxycyclohexane carboxylate; and bis(3, 4-epoxycyclohexylmethyl) adipate. Two common photoinitiators are mixed triarylsulfonium hexafluoroantimonate salts; and (4-methylphenyl)[4-(2-methylpropyl) phenyl]iodonium hexafluorophosphate. UV-curable adhesives containing mercapto ester and isocyanuarte should also provide robust bonding between glass-to-glass or glass-to-metal layers of the PV module (e.g., NOA61, NOA71, NOA81 made by Norland). Whereas the first glass frit 40 can have a Youngs modulus of >50 GPa, the polymeric seal 30 can have a Youngs modulus of <20 GPa.

Referring again to the PV module 100 depicted in FIGS. 1, 1A, the module includes a first glass frit 40 that is disposed between and in contact with the outer glass layer 50 and inner glass layer 60. In embodiments, the first glass frit 40 is selected to adhere the outer and inner glass layers 50, 60 together, e.g., after deposition, sintering and/or irradiation. Any suitable glass frit paste may be used for the first glass frit 40. In general, it is desirable for the glass frit paste used for the first glass frit 40 to have a similar coefficient of thermal expansion (CTE) as the outer and inner glass layers 50, 60. For example, the glass frit paste can have a CTE of ~2.9 to ~3.3 ppm/° C., or ~3.1 ppm/° C. This helps prevent the first glass frit 40 and the glass layers 50, 60 from separating during a laser irradiation step due to differences in the rate at which the materials expand when heated.

Table 1 below provides examples of suitable compositions of the glass frit paste suitable for use in the first glass frit 40. As shown in the table, each of the glass frit paste compositions includes at least 50% glass. The glass in the glass frit paste can have any suitable composition. Examples of suitable glass compositions include those given for Glass A and Glass B in Table 2 and Table 3, respectively. In one implementation, the first glass frit 40 employs a Corning® HCP-50 composition given by: 13.80 wt. % BCA, 2-(2-butoxyethoxy) ethyl acetate), 32.20 wt. % terpineol, 4.00 wt. % Dow® 200 ethyl cellulose, and 50.00 wt. % glass (e.g., Glass A or Glass B in Tables 2 and 3, respectively).

TABLE 1
Glass frit paste compositions

| | Glass Frit (wt %) | | | | | | | | | |
|---|---|---|---|---|---|---|---|---|---|---|
| Material | 1 | 2 | 3 | 4 | 5 | 6 | 7 | 8 | 9 | 10 |
| fine filler | No | No | No | No | No | No | No | Yes | No | No |
| T100 | — | 1.13 | 0.95 | 0.78 | 0.62 | 0.62 | — | — | — | — |
| texanol | — | 11.81 | 9.95 | 8.18 | 19.96 | 19.91 | — | — | — | — |
| BCA | — | — | — | — | — | — | 43.17 | 43.17 | 43.17 | 43.17 |
| 9000 | — | 0.65 | — | 1.14 | — | — | — | — | — | 1 |
| Glass | 63.32 | 66.47 | 69.88 | 74 | 64.29 | 64.33 | 50 | 50 | 50 | 50 |
| Dow 200 EC | — | — | — | — | — | — | 5.83 | 5.83 | 5.83 | 5.59 |
| 202 | 0.2 | 0.98 | 1.4 | 0.81 | 0.84 | 0.86 | — | — | — | 1 |
| 354 | — | 0.65 | — | 0.5 | — | — | 1 | 1 | 1 | 1 |
| dibutyl | — | 13.39 | 11.88 | 9.73 | — | — | — | — | — | — |
| phthalate | | | | | | | | | | |
| Poly G 20-265 | — | — | 5.94 | 4.86 | 13.45 | — | — | — | — | — |
| Poly G 20-56 | 36.47 | 4.92 | — | — | — | 13.44 | — | — | — | — |
| OC-60 | — | — | — | — | 0.84 | 0.84 | — | — | — | — |

TABLE 2
Glass A composition (mol %)

| | |
|---|---|
| V₂O₅ | 47.5 |
| P₂O₅ | 22.5 |
| Fe₂O₃ | 15 |
| TiO₂ | 7.5 |
| ZnO | 2.5 |
| B₂O₃ | 5 |

TABLE 3
Glass B composition (mol %)

| | |
|---|---|
| SiO₂ | 59 |
| Al₂O₃ | 19.6 |
| Li₂O | 6.8 |
| ZnO | 12.4 |
| ZrO₂ | 2.2 |

Still referring to the PV module depicted in FIGS. 1, IA, the glass frit paste used in the first glass frit 40 can be applied in any suitable thickness, width, and/or quantity. It can also be applied at any suitable speed. In general, the thickness of the glass frit paste used for the first glass frit 40 should be sufficient to provide the required spacing between the outer and inner glass layers 50, 60 (e.g., as defining the gap 70). In some embodiments, the thickness of the applied glass frit paste is from ~3 μm to ~50 μm, ~3 μm to ~20 μm, or from ~5 μm to ~20 μm.

The width of the glass frit paste used for the first glass frit 40 between the outer and inner glass layers 50, 60 should be sufficient to provide a hermetic seal. In some embodiments, the glass frit paste is applied to form the first glass frit 40 in lines having a width 42 of from ~100 μm to ~1 mm, ~250 μm to ~1 mm, ~500 μm to ~1 mm, ~750 μm to ~1 mm, ~0.1 mm to ~1 mm, or ~0.3 mm to ~0.7 mm. For example, and as noted earlier, the width 42 of the first glass frit 40 can be 100 μm, 150 μm, 200 μm, 250 μm, 300 μm, 350 μm, 400 μm, 450 μm, 500 μm, 550 μm, 600 μm, 650 μm, 700 μm, 750 μm, 800 μm, and other widths 42 between the foregoing width values. As noted earlier, the width 42 of the first glass frit 40 can vary along the perimeter of the device and does not need to have one fixed or constant value.

Referring again to the PV module depicted in exemplary form in FIGS. 1, 1A, the glass frit paste used for the first glass frit 40 can be applied to the inner glass layer 60 (or the outer glass layer 50) using any suitable process and/or technology. For example, the glass frit paste can be deposited on the inner glass layer 60 using a pen dispenser, screen printer, inkjet printer, aerosol jet, or the like. One of the advantages of using a pen dispenser is that it uses frit efficiently and is better suited for depositing small amounts of frit. Screen printing uses frit less efficiently than pen-dispensing and takes more time to prepare, but screen printing is capable of higher throughput, which potentially makes it generally more suitable for mass production. Both pen-dispensing and screen printing may be used to evenly apply the glass frit paste of the first glass frit 40 on the outer glass layer 50. After sintering (e.g., at 380° C. for 60 minutes) and irradiation (e.g., laser irradiation at 10-15 W), the resulting first glass frit 40 has a width 42 and portions 44 that are in contact with the outer and inner glass layers 50, 60 (see FIGS. 1, 1A).

Without being bound by theory, the reliability of the PV module 100 depicted in FIGS. 1, 1A upon exposure to extreme climate conditions (water, moisture and oxygen exposure at elevated temperatures), e.g., as set forth in the 85/85 Test, and the reliability of the other PV modules of the disclosure, can surprisingly be enhanced through the use of the dual seal (polymeric and glass frit) arrangement in these modules. In some implementations of the PV module 100 depicted in FIGS. 1, 1A, the module exhibits no failures at the polymeric seal 30 or first glass frit 40 after 500, 600, 750, 800, 900, 1000, 1100, 1200, 1300, 1400, or even 1500 hours of exposure at 85° C. and 85% relative humidity according to the 85/85 Test.

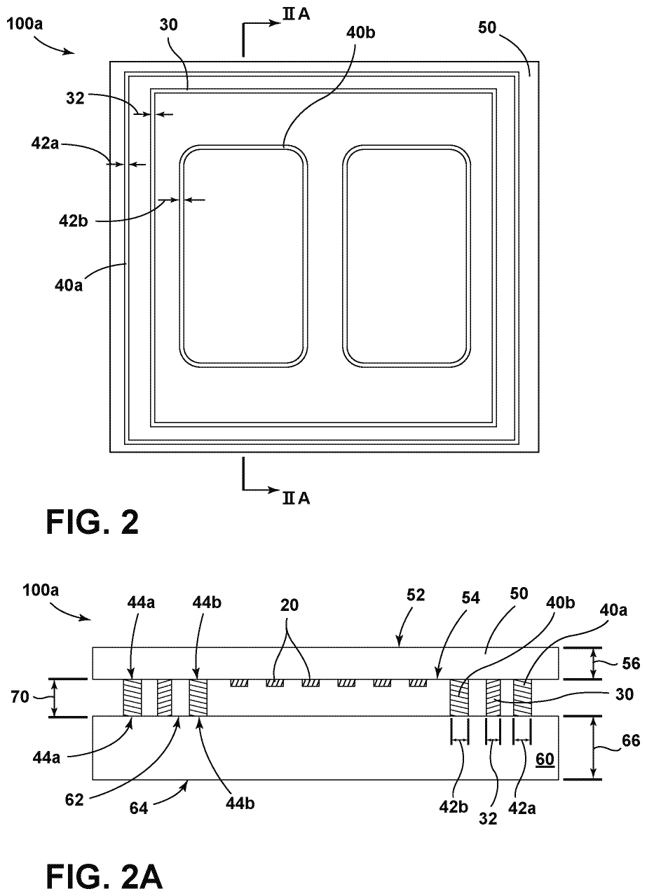

Referring now to the PV module 100a depicted in exemplary form in FIGS. 2, 2A, this module has substantially the same structure and function as the PV module 100 shown in FIGS. 1, 1A, with common elements having materially the same structure and function. In addition, however, the PV module 100a depicted in FIGS. 2, 2A includes a first glass frit 44b disposed between and in contact with the inner and outer glass layers 60, 50; and a second glass frit 44a disposed between and in contact with the inner and outer glass layers 60, 50. Further, each of seal widths 42b, 42a of the first and second glass frits 40b, 40a is at least 100 μm, 200 jμm, 300 μm, 400 jμm, 500 μm, or 600 μm. The seal widths 42b, 42a do not need to be the same or even constant along the device perimeter. In some embodiments, the first glass frit 40b is inboard of the polymeric seal 30. According to an implementation, the second glass frit 40a is outboard of the polymeric seal 30. In addition, a portion 44b of the first glass frit 40b and a portion 44a of the second glass frit 40a is in contact with the inner and outer glass layers 60, 50, with each of the portions 44b, 44a having an average bond width that is at least 90% of the seal width 42b, 42a of the first and second glass frits 40b, 40a, respectively.

Comparable to the PV module 100 depicted in FIGS. 1, 1A, the PV module 100a shown in FIGS. 2, 2A and detailed above also exhibits no failures at the polymeric seal 30 or glass frits 40b, 40a after 1200 hours of exposure at 85° C. and 85% relative humidity according to the 85/85 Test. Without being bound by theory, the arrangement of PV module 100a can provide enhanced reliability, as the outermost second glass frit 40a can serve to provide increased resistance to moisture and gaseous ingress. Indeed, the combination of two glass frits 40b, 40a and the polymeric seal 30 can provide enhanced reliability in the face of both liquid water exposure (e.g., from precipitation) and moisture at elevated temperatures. In some implementations of the PV module 100a depicted in FIGS. 2, 2A, the module exhibits no failures at the polymeric seal 30 or glass frits 40b, 40a after 500, 600, 750, 800, 900, 1000, 1100, 1200, 1300, 1400, or even 1500 hours of exposure at 85° C. and 85% relative humidity according to the 85/85 Test. As shown in the figures, the frit and/or polymeric seals can encapsulate multiple PV devices simultaneously. In contrast, the frit and/or polymer seals can be used to encapsulate only a single PV device. The sealing may traverse along glass surfaces, but it may traverse over metal, transparent conductor, polymer, dielectric, semiconductor, conductor, or other surfaces.

Referring again to the PV modules 100, 100a depicted in FIGS. 1-2A, the polymeric seal 30 and glass frits 40, 40a, and 40b of these modules can be formed in various patterns between the outer and inner glass layers 50, 60. For example, the patterns can be isolated along the perimeter of the glass layers 50, 60 or, in some embodiments, they can be irregularly shaped. In some embodiments, and as shown in FIGS. 1-2A, the first glass frit 40 or 40b can be arranged in a pattern with two or more regions containing one or more PV structures 20 (not shown). In other embodiments, the glass frits 40 and 40a can be arranged to form a single region or zone that encompasses the one or more PV structures 20 of the modules 100, 100a.

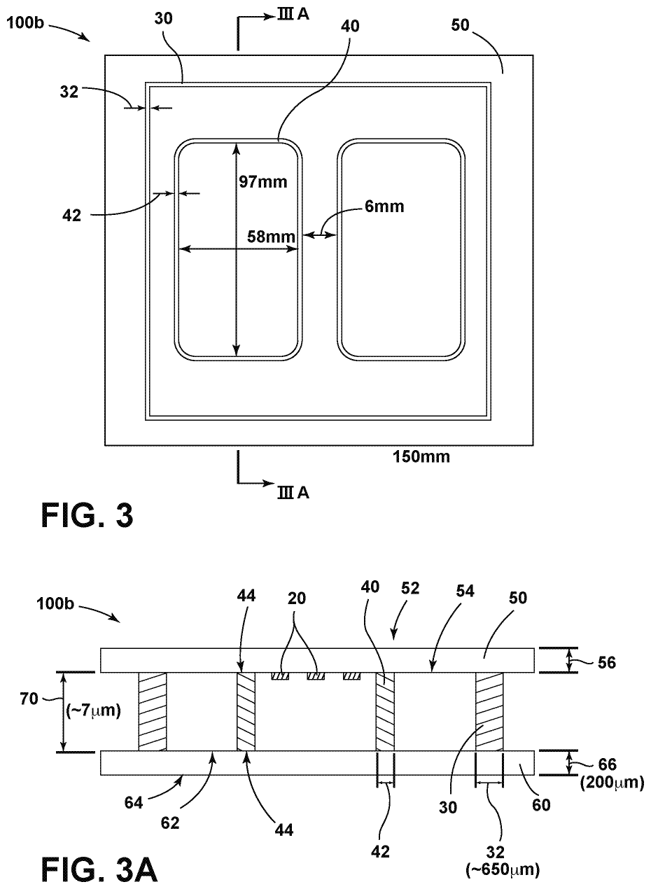

Referring now to FIGS. 3, 3A, an exemplary PV module 100b is depicted with a particularized arrangement to demonstrate the broader concepts elucidated in this disclosure. In particular, the PV module 100b has substantially the same structure and function as the PV module 100 shown in FIGS. 1, 1A, with common elements having materially the same structure and function. Further, the first glass frit 40 is arranged inboard of the polymeric seal 30 in a pattern with two rectangularly shaped zones that encompass the one or more PV structures 20 (not shown). Each of the zones has a width of about 58 mm and length of about 97 mm, with the zones separated by a gap of about 6 mm. In addition, the outer and inner glass layers 50, 60 are in a square shape of about 150 mm×150 mm. In addition, the gap 70 between the layers 50, 60 is about 7 μm, the width 42 of the first glass frit 40 is about 650 μm and the thickness 56, 66 of the outer and inner glass layers 50, 60 is about 200 μm. In addition, the PV module 100b depicted in FIGS. 3, 3A is expected to exhibit no failures at the polymeric seal 30 or first glass frit 40 after 500, 600, 750, 800, 900, 1000, 1100, 1200, 1300, 1400, or even 1500 hours of exposure at 85° C. and 85% relative humidity according to the 85/85 Test.

Referring again to the PV modules 100-100b depicted in FIGS. 1-3A, each of these modules is surprisingly configured to exhibit enhanced reliability upon exposure to extreme climate conditions (e.g., no failures after 1200 hours of exposure at 85° C. and 85% relative humidity according to the 85/85 Test). Without being bound by theory, the use of at least one glass frit and at least one polymeric seal in each of these modules 100-100b provides surprising benefits and advantages. As shown in these figures and described above, the sealing arrangement in these modules includes at least one glass frit seal and at least one non-frit seal placed outboard of the frit. The purpose of the glass frit seal is to provide hermetic encapsulation of the device and prevent ingress of oxygen and moisture. Glass frit has been proven to perform this role in multiple indoor controlled-environment applications. The glass frit bonds to the outer and inner glass layers, and creates a benchmark barrier that is strong in compression.

However, the inclusion of the polymeric seal in these modules 100-100b (see FIGS. 1-3A) also avoids a potential failure mechanism associated with the glass frit, particularly exposure to uncontrolled environmental or weather conditions. These conditions include exposure to water over extended periods of time that is combined with corrosive components. Rain, for example, may have a variety of pH levels. “Normal rain” is assumed to have a pH of 5-5.5. Pollutants can easily reduce rain pH to 4.2-4.4, though, or expand the pH range to 4-6. Corrosive water could degrade glass frit seal integrity over a 30-year lifetime. Indeed, modules with only a glass frit seal did not survive being placed outdoors in Mumbai, India during a 26-day period with high rainfall. The glass frit seal was observed to fail, the frit yellowed, and water penetrated the sealed device. Further, other environmental conditions, including water freezing and expanding, can create mechanical failure modes as well. Nevertheless, the overall sealing strategy employed by the PV modules addresses these concerns by employing an additional polymeric seal besides the glass frit seal. The non-glass frit seal, i.e., the polymeric seal, ensures that water and other environmental elements do not degrade the glass frit seal, allowing the glass frit to provide the primary hermeticity function without experiencing degradation over time. In addition, the frit and polymeric seals vary in thermal expansion, Youngs Modulus, and adhesive characteristics that allow them to work in a complementary manner and achieve an extended lifetime hermetic seal.

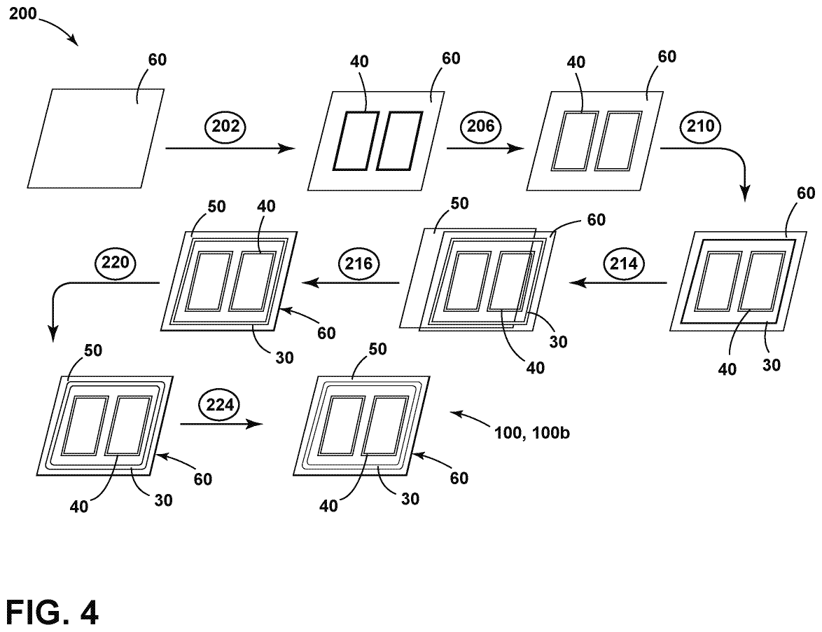

Referring now to FIG. 4, a flow chart schematic is provided of a method 200 of making a photovoltaic module (e.g., PV module 100 shown in FIGS. 1, 1A). The exemplary method 200 as depicted in FIG. 4 has various steps, which can be conducted according to the sequence shown in the figure. In other embodiments, these steps can be conducted in different sequences, as technically feasible as understood by those skilled in the field of the disclosure. As depicted in FIG. 4, the method 200 includes: a step 202 of dispensing a first glass frit (e.g., glass frit 40) on an inner glass layer (e.g., glass layer 60), the first glass frit 40 defining a seal width 42 of at least about 400 μm. According to some embodiments, the step 202 of dispensing is conducted according to a conventional screen printing or dispensing process. In some embodiments, the step 202 is conducted with a dispenser having a diameter of 0.5 mm, a dispensing pressure of 40 kPa and a dispensing speed of 20 mm/s. Using these parameters, a glass frit can be dispensed with a 0.7 mm width and a wet height of about 15 μm. In some embodiments, the outer and inner glass layers are square-shaped at 4″×4″ in dimension, but can be smaller or larger depending on tooling and the desired size of the ultimate PV module. As noted earlier, the glass layers can have the same or differing thicknesses, e.g., 0.1 mm for the outer layer and 0.5 mm for the inner layer. Further, the glass layers can be subjected to a cleaning process before the dispensing step 202, e.g., with a Parker or SC1 system, as understood by those skilled in the field of this disclosure.

Next, the method 200 depicted in FIG. 4 includes a step of positioning a plurality of photovoltaic (PV) structures (e.g., one or more PV structures 20, as shown in FIG. 1) on the inner glass layer, typically inboard of the glass frit seal (not shown). The PV structures according to this step can be arranged using any of a variety of conventional approaches employed in the field of PV modules and related technology.

Referring again to FIG. 4, the method 200 of making a PV module also includes a step 206 of sintering the first glass frit residing on the glass layer. In step 206, the sintering of the glass frit removes organics and solvent(s). In one implementation, step 206 is conducted by heating the glass layer and glass frit to 325° C. at a heating rate of 10° C./min, followed by a hold for about 20 minutes; then the glass layer and glass frit is ramped upward to about 380° C. at a heating rate of 10° C./min, followed by a hold for about 60 minutes; and then the glass layer and glass frit is cooled back down to ambient temperature, e.g., a furnace cooling rate. Other sintering profiles can be employed as readily understood by those skilled in the field of this disclosure, e.g., as a function of the composition of the glass frit, thickness of the glass layer, furnace equipment and other considerations. Typically, after step 206 has been conducted, the glass frit is substantially denser and cannot be wiped off of the glass layer (e.g., inner glass layer).

Still referring to FIG. 4, the method 200 of making a PV module includes a step 210 of dispensing a polymeric seal (e.g., polymeric seal 30) on the inner glass layer 60. Various approaches can be employed in step 210 to dispense the polymeric seal, including screen printing and dispensing processes. In one exemplary implementation, step 210 is conducted using a UV-curable epoxy resin with a dispensing process by adjusting dispensing speed (Vd), dispensing gap (H), dispensing pump pressure (P), and dispensing needle diameter (D). With these parameters, the following process window can be used to conduct step 210: 10 mm/s<Vd<50 mm/s; H>10 μm; 10 kPa<P<200 kPa; and D>20 μm. As understood by those skilled in the field of this disclosure, other process windows can be employed in step 210, typically as a function of the composition of the polymeric seal used in this step.

The method 200 also includes a step 214 of positioning an outer glass layer (e.g., outer glass layer 50) in contact with the first glass frit and the polymeric seal, the positioning conducted such that the first glass frit and the polymeric seal are disposed between and in contact with the inner and outer glass layers. In some embodiments, a weight (e.g., a small iron sheet) is employed in step 214 to further control the positioning of the glass layers and uniform squeezing and movement of the polymeric seal within the layers prior to the subsequent irradiation and curing steps. According to some embodiments, one or both of the glass layers (with an iron weight) is placed on an electro-magnetic stage and the magnetic force can be adjusted through coil current control to further position the glass layers and control the gap between the glass layers, width of the polymeric seal, and other pertinent dimensions of the module.

Referring again to the method 200 depicted in FIG. 4, the method can include an optional step 216 of applying a vacuum to the module (e.g., glass layers, glass frit, and polymeric seal) at a pressure of less than 0.4 mbar for more than 30 seconds, the step 216 of applying the vacuum conducted after the step 214 of positioning and before the step 220 of irradiating the glass frit (see below). Without being bound by theory, the step 216 of applying a vacuum pressure forces the glass layers to reflow the polymeric seal such that it reaches the same height as the glass frit, thus setting a more uniform gap between the layers. In turn, the more uniform gap ensures that the bond formed by the glass frit after the subsequent irradiating step 220 is uniform and the portion of the glass frit in contact with the glass layers is substantially the same as the width of the glass frit. Conversely, if the height of the polymeric seal is not uniform between the glass layers, the subsequent irradiating step 220 can result in non-uniform glass frit bonds between the glass layers, leading to cracking and delamination.

Further, the method 200 of FIG. 4 includes a step 220 of irradiating the glass frit with a laser such that a portion of the first glass frit is in contact with the inner and outer glass layers, the portion having an average bond width that is at least 90% of the seal width of the first glass frit. In some embodiments, the irradiating step 220 is conducted by applying a laser beam through one of the glass layers upon the sintered glass frit at a power from 10 to 15 W at 10 to 30 mm/s. According to an embodiment, the step 220 of irradiating the glass frit can be conducted with a laser at a power of 12.5 W at 20 mm/s.

Finally, the method 200 includes a step 224 of curing the polymeric seal. The curing conditions as part of step 224 are set based on the composition of the polymeric seal and the energy employed to effect the cure (e.g., thermal energy, UV energy, etc.). For example, many UV epoxy resins serving as a polymeric seal can be cured with UV radiation for a short time, e.g., at least one minute. The PV module produced by the method 200 can be substantially flat or curved based on the application requirements. If curved or shaped, the curvature or shape can be generated as the device module is assembled, or the module can be shaped after sealing. Also, if curved or shaped, the polymeric or frit seal width in contact with the convex glass layer can be larger or smaller than the width in contact with the concave glass layer.

### EXAMPLES

Various embodiments of the PV modules of the disclosure will be further clarified by the following examples.

### Example 1

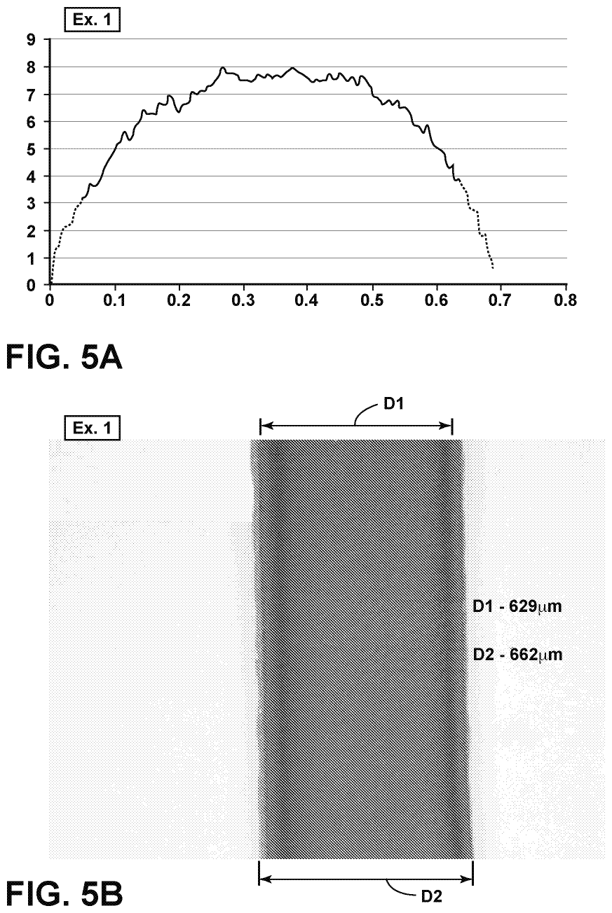

In this example, a Corning® HCP-50 glass frit is printed onto an inner glass layer by a screen printing method. The glass frit is then sintered by heating the glass layer and glass frit to 325° C. at a ramp rate of 10° C./min and then held for 20 minutes. The glass layer and glass frit is then ramped up to 380° C. at the same ramp rate and held for another 60 minutes, followed by a cool down. Referring now to FIG. 5A, a height profile is shown of the sintered glass frit on a glass layer from this example (designated “Ex. 1”). As is evident from this figure, the average height of the glass frit is about 7 μm and its cross-sectional profile is round in shape.

Also in this example, an outer glass layer was positioned over the sintered glass frit and inner glass layer on an electro-magnetic stage. Several iron bars were then added to the outer glass layer to increase contact between the glass frit and the glass layers. A laser was then used to irradiate along the frit pattern at 12.5 W at a scan speed of 20 mm/s. Referring now to FIG. 5B, an optical micrograph is provided of a top-down view of the sintered and irradiated glass frit of this example (Ex. 1), which has formed a seal between the two glass layers. As is evident from this figure, the Corning® HCP-50 glass frit has formed an effective seal with no delamination and the portion of the glass frit in contact with the glass layers (D1, ~629 m) is greater than 95% of the width of the glass frit (D2, ~662 m).

### Example 2

In this example, an epoxy resin serving as a polymeric seal was deposited on a glass layer with a sintered glass frit seal in a manner in which the height of the polymeric seal was greater than the height of the frit. An outer glass layer was then positioned over the glass layer with the frit and polymeric seal. In this case, the resulting comparative module (designated “Comp. Exs. 1A and 1B”) had an epoxy thickness that was not uniform given that its height was substantially greater than the height of the glass frit. Further, in this example, the glass frit was then subjected to an irradiation step according to the parameters employed in the prior example.

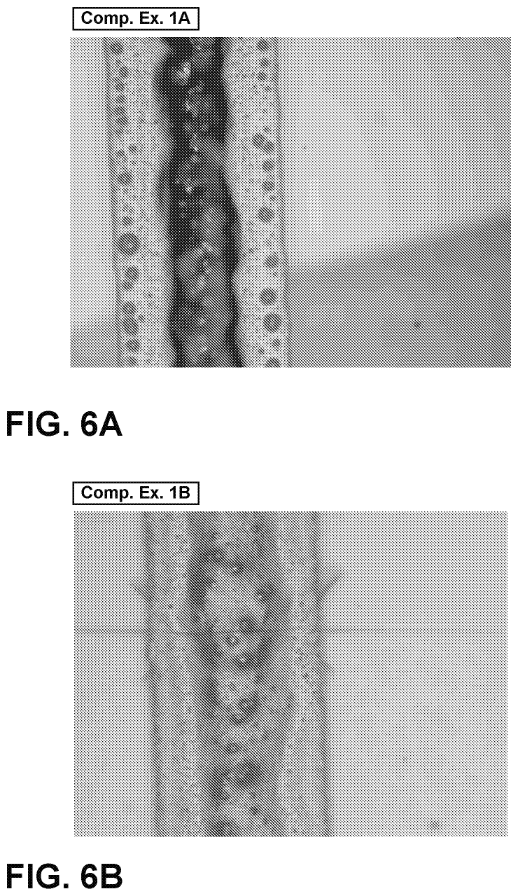

Referring now to FIGS. 6A and 6B, optical micrographs are provided of a top-down view of the comparative as-irradiated glass frit seals from this example (Comp. Exs. 1A and 1B) in sample photovoltaic modules that also include polymeric seals. In FIG. 6A, the seal is shown with a delamination failure mode. In FIG. 6B, the seal is shown with a cracking failure mode.

To remedy the problems observed in FIGS. 6A and 6B, samples were prepared in the same manner, but with an additional vacuum step before the irradiation step (designated “Exs. 2A and 2B”). The vacuum step was conducted according to the methods outlined earlier in this disclosure (e.g., at a pressure of less than 0.4 mbar for more than 30 seconds).

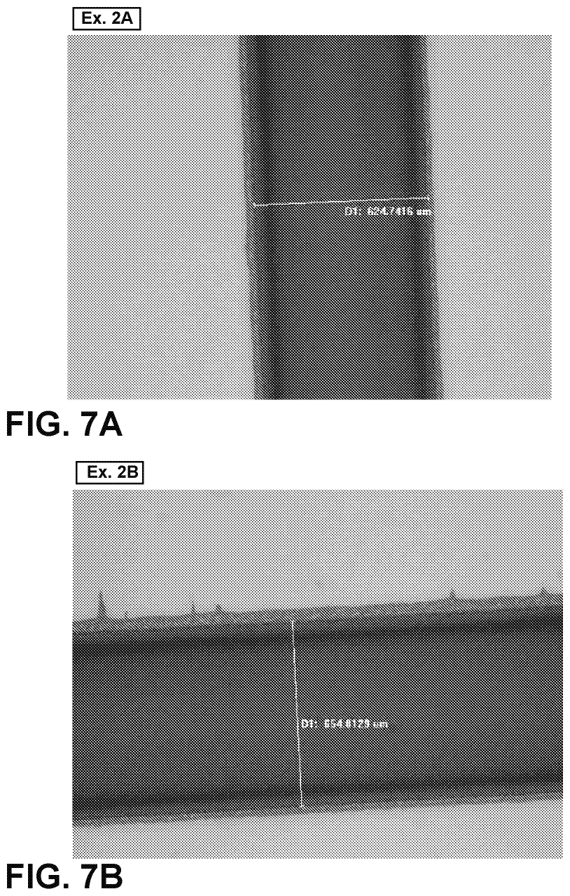

Referring now to FIGS. 7A and 7B, optical micrographs are provided of a top-down view of the as-irradiated glass frit seals of the photovoltaic modules of this example (that also include polymeric seals). As is evident from these figures, the glass frit seals of these modules had portions in contact with the glass layers that were at least 90% of the width of the glass frits with no delamination and cracks (i.e., D1=624.7 μm and 654.8 μm in FIGS. 7A and 7B, respectively). As such, the additional vacuum step employed in these examples was particularly beneficial in ensuring that the glass frit seals experienced no failures and exhibit a substantial portion in contact with the glass layers.

### Examples 3-5

In these examples, three sets of PV modules were prepared according to the same conditions of the prior inventive example with polymeric and glass frit seals (designated “Exs. 3A, 3B, 4A, 4B, 5A and 5B”). After formation of these PV modules, including steps of irradiating the glass frit and curing the polymeric seals, the modules were exposed to accelerated environmental testing at 85° C. in 85% relative humidity according to the 85/85 Test for 1200 hours.

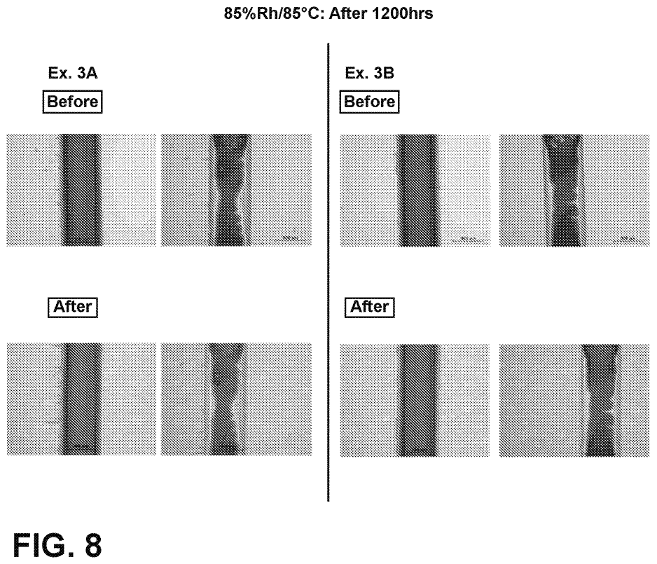

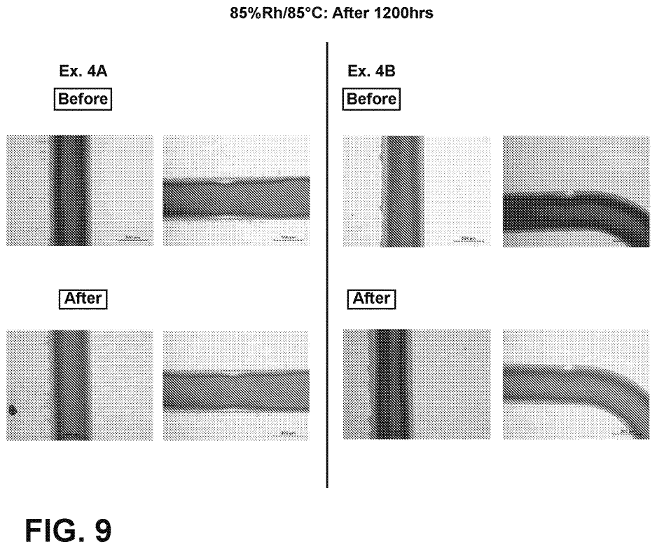

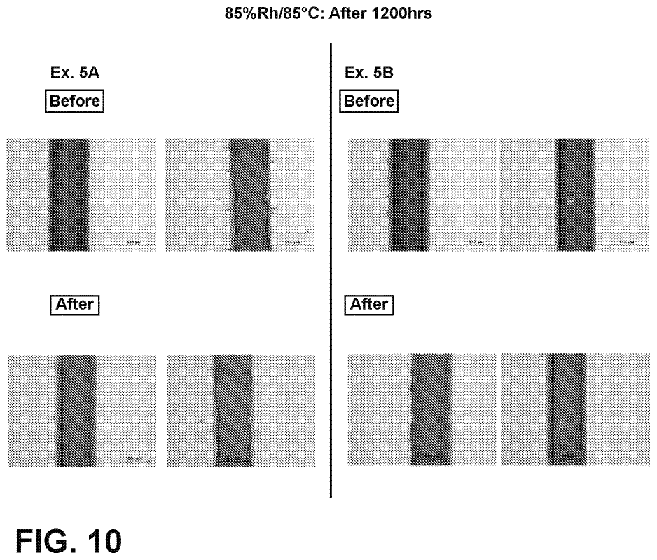

Referring now to FIGS. 8-10, optical micrographs are provided of a top-down view of as-irradiated glass frit seals of the photovoltaic modules of this example (that also include polymeric seals), as subjected to the 85/85 Test (Exs. 3A-5B). Indeed, all of the PV modules of these examples did not experience any failures from the 85/85 Test, as is evident from the seals shown in these figures. In particular, these PV modules remained watertight during and after the 85/85 Test and any observed defects in the seals did not propagate from the exposure associated with the 85/85 Test.

The various features described in the specification may be combined in any and all combinations, for example, as listed in the following embodiments.

Embodiment 1. A photovoltaic module is provided that includes: an outer glass layer; an inner glass layer; one or more photovoltaic (PV) structures disposed on the outer glass layer, inner glass layer or between the layers; a polymeric seal disposed between and in contact with the inner and outer glass layers; and a first glass frit disposed between and in contact with the inner and outer glass layers. The seal width of the first glass frit is at least about 100 μm. Further, the module exhibits no failures at the polymeric seal or first glass frit after 1200 hours of exposure at 85° C. and 85% relative humidity according to the IEC 61215 Damp Heat Test.

Embodiment 2. The photovoltaic module of Embodiment 1 is provided, wherein the first glass frit is inboard of the polymeric seal.

Embodiment 3. The photovoltaic module of Embodiment 1 or Embodiment 2 is provided, wherein the first glass frit and the polymeric seal define a gap between the inner and outer glass layers, the gap from about 1 to 20 μm.

Embodiment 4. The photovoltaic module of any one of Embodiments 1-3 is provided, wherein a portion of the first glass frit is in contact with the inner and outer glass layers, the portion having an average bond width that is at least 90% of the seal width of the first glass frit.

Embodiment 5. The photovoltaic module of any one of Embodiments 1-4 is provided, wherein the seal width of the first glass frit is at least about 600 μm.

Embodiment 6. The photovoltaic module of any one of Embodiments 1-5 is provided, wherein the polymeric seal comprises one or more adhesives selected from the group consisting of silicone, epoxy, thermoplastic polyolefin (TPO), polyolefin (PO), polyvinyl butyral (PVB), and ethylene vinyl acetate (EVA) adhesives.

Embodiment 7. The photovoltaic module of any one of Embodiments 1-6 is provided, wherein each of the glass layers exhibits a coefficient of thermal expansion (CTE) of less than 10 ppm/° C. and the polymeric seal exhibits a CTE of 50 to 200 ppm/° C.

Embodiment 8. The photovoltaic module of any one of Embodiments 1-7 is provided, wherein each PV structure is one of a CdTe, amorphous silicon (a-Si), polysilicon (p-Si), CuIn/GaSe (CIGS), and perovskite (ABX3) thin-film PV structure.

Embodiment 9. A photovoltaic module is provided that includes an outer glass layer; an inner glass layer; one or more photovoltaic (PV) structures disposed on the outer glass layer, inner glass layer or between the layers; a polymeric seal disposed between and in contact with the inner and outer glass layers; a first glass frit disposed between and in contact with the inner and outer glass layers; and a second glass frit disposed between and in contact with the inner and outer glass layers. The seal width of the first and second glass frits is at least about 100 μm. Further, the module exhibits no failures at the polymeric seal or glass frits after 1200 hours of exposure at 85° C. and 85% relative humidity according to the IEC 61215 Damp Heat Test.

Embodiment 10. The photovoltaic module of Embodiment 9 is provided, wherein the first glass frit is inboard of the polymeric seal.

Embodiment 11. The photovoltaic module of Embodiment 10 is provided, wherein the second glass frit is outboard of the polymeric seal.

Embodiment 12. The photovoltaic module of any one of Embodiments 9-11 is provided, wherein the first glass frit, the second glass frit and the polymeric seal define a gap between the inner and outer glass layers, the gap from about 1 to 20 μm.

Embodiment 13. The photovoltaic module of any one of Embodiments 9-12 is provided, wherein a portion of the first glass frit and a portion of the second glass frit is in contact with the inner and outer glass layers, each of the portions having an average bond width that is at least 90% of the seal width of the first and second glass frits.

Embodiment 14. The photovoltaic module of any one of Embodiments 9-13 is provided, wherein the seal width of the first and second glass frits is at least about 600 μm.

Embodiment 15. The photovoltaic module of any one of Embodiments 9-14 is provided, wherein the polymeric seal comprises one or more adhesives selected from the group consisting of silicone, epoxy, thermoplastic polyolefin (TPO), polyolefin (PO), polyvinyl butyral (PVB), and ethylene vinyl acetate (EVA) adhesives.

Embodiment 16. The photovoltaic module of any one of Embodiments 9-15 is provided, wherein each of the glass layers exhibits a coefficient of thermal expansion (CTE) of less than 10 ppm/° C. and the polymeric seal exhibits a CTE of 50 to 200 ppm/° C.

Embodiment 17. A method of making photovoltaic module is provided that includes the following steps: dispensing a first glass frit on an inner glass layer, the first glass frit defining a seal width of at least about 100 μm; positioning one or more photovoltaic (PV) structures on the inner glass layer; sintering the first glass frit; dispensing a polymeric seal on the inner glass layer; positioning an outer glass layer in contact with the first glass frit and the polymeric seal, the positioning conducted such that the first glass frit and the polymeric seal are disposed between and in contact with the inner and outer glass layers; irradiating the glass frit with a laser such that a portion of the first glass frit is in contact with the inner and outer glass layers, the portion having an average bond width that is at least 90% of the seal width of the first glass frit; and curing the polymeric seal.

Embodiment 18. The method of making a photovoltaic module of Embodiment 17 is provided, wherein the module exhibits no failures at the polymeric seal and first glass frit after 1200 hours of exposure at 85° C. and 85% relative humidity according to the IEC 61215 Damp Heat Test.

Embodiment 19. The method of making a photovoltaic module of Embodiment 17 or Embodiment 18 is provided, wherein the first glass frit is inboard of the polymeric seal.

Embodiment 20. The method of making a photovoltaic module of any one of Embodiments 17-19 is provided, further including applying a vacuum to the module at a pressure of less than 0.4 mbar for more than 30 seconds, the applying conducted after the positioning and before the irradiating.

1. A photovoltaic module, comprising:
an outer glass layer;
an inner glass layer;
one or more photovoltaic (PV) structures disposed on the outer glass layer, inner glass layer or between the layers;
a polymeric seal disposed between and in contact with the inner and outer glass layers; and
a first glass frit disposed between and in contact with the inner and outer glass layers,
wherein a seal width of the first glass frit is at least about 100 μm, and
further wherein the module exhibits no failures at the polymeric seal or first glass frit after 1200 hours of exposure at 85° C. and 85% relative humidity according to the IEC 61215 Damp Heat Test.

2. The module according to claim 1, wherein the first glass frit is inboard of the polymeric seal.

3. The module according to claim 1, wherein the first glass frit and the polymeric seal define a gap between the inner and outer glass layers, the gap from about 1 to 20 μm.

4. The module according to claim 1, wherein a portion of the first glass frit is in contact with the inner and outer glass layers, the portion having an average bond width that is at least 90% of the seal width of the first glass frit.

5. The module according to claim 1, wherein the seal width of the first glass frit is at least about 600 μm.

6. The module according to claim 1, wherein the polymeric seal comprises one or more adhesives selected from the group consisting of silicone, epoxy, thermoplastic polyolefin (TPO), polyolefin (PO), polyvinyl butyral (PVB), and ethylene vinyl acetate (EVA) adhesives.

7. The module according to claim 1, wherein each of the glass layers exhibits a coefficient of thermal expansion (CTE) of less than 10 ppm/° C. and the polymeric seal exhibits a CTE of 50 to 200 ppm/° C.

8. The module according to claim 1, wherein each PV structure is one of a CdTe, amorphous silicon (a-Si), polysilicon (p-Si), CuIn/GaSe (CIGS), and perovskite (ABX₃) thin-film PV structure.

9. A photovoltaic module, comprising:
an outer glass layer;
an inner glass layer;
one or more photovoltaic (PV) structures disposed on the outer glass layer, inner glass layer or between the layers;
a polymeric seal disposed between and in contact with the inner and outer glass layers;
a first glass frit disposed between and in contact with the inner and outer glass layers; and
a second glass frit disposed between and in contact with the inner and outer glass layers,
wherein a seal width of the first and second glass frits is at least about 100 μm, and
further wherein the module exhibits no failures at the polymeric seal or glass frits after 1200 hours of exposure at 85° C. and 85% relative humidity according to the IEC 61215 Damp Heat Test.

10. The module according to claim 9, wherein the first glass frit is inboard of the polymeric seal.

11. The module according to claim 10, wherein the second glass frit is outboard of the polymeric seal.

12. The module according to claim 9, wherein the first glass frit, the second glass frit and the polymeric seal define a gap between the inner and outer glass layers, the gap from about 1 to 20 μm.

13. The module according to claim 9, wherein a portion of the first glass frit and a portion of the second glass frit is in contact with the inner and outer glass layers, each of the portions having an average bond width that is at least 90% of the seal width of the first and second glass frits.

14. The module according to claim 9, wherein the seal width of the first and second glass frits is at least about 600 μm.

15. The module according to claim 9, wherein the polymeric seal comprises one or more adhesives selected from the group consisting of silicone, epoxy, thermoplastic polyolefin (TPO), polyolefin (PO), polyvinyl butyral (PVB), and ethylene vinyl acetate (EVA) adhesives.

16. The module according to claim 9, wherein each of the glass layers exhibits a coefficient of thermal expansion (CTE) of less than 10 ppm/° C. and the polymeric seal exhibits a CTE of 50 to 200 ppm/° C.

17. A method of making a photovoltaic module, comprising:
dispensing a first glass frit on an inner glass layer, the first glass frit defining a seal width of at least about 100 μm;
positioning one or more photovoltaic (PV) structures on the inner glass layer;
sintering the first glass frit;
dispensing a polymeric seal on the inner glass layer;
positioning an outer glass layer in contact with the first glass frit and the polymeric seal, the positioning conducted such that the first glass frit and the polymeric seal are disposed between and in contact with the inner and outer glass layers;
irradiating the glass frit with a laser such that a portion of the first glass frit is in contact with the inner and outer glass layers, the portion having an average bond width that is at least 90% of the seal width of the first glass frit; and
curing the polymeric seal.

18. The method according to claim 17, wherein the module exhibits no failures at the polymeric seal and first glass frit after 1200 hours of exposure at 85° C. and 85% relative humidity according to the IEC 61215 Damp Heat Test.

19. The method according to claim 17, wherein the first glass frit is inboard of the polymeric seal.

20. The method according to claim 17, further comprising:
applying a vacuum to the module at a pressure of less than 0.4 mbar for more than 30 seconds, the applying conducted after the positioning and before the irradiating.
